(19) United States
(12) Patent Application Publication
(10) Pub. No.: US 2002/0126861 A1
(43) Pub. Date: Sep. 12, 2002

(54) Audio expander

(76) Inventor: Chester Colby, New London, CT (US)

Correspondence Address: Richard W. Goldstein, 2071 Clove Road, Staten Island, NY, 10304, US

(21) Appl. No.: 09/805,007

(22) Filed: Mar. 12, 2001

(51) Int. Cl. H03F 21/00; H03G 7/00

(52) U.S. Cl. 381/106

(57) ABSTRACT

A dynamic range expander circuit is arranged to receive and process an input audio signal to provide an expanded output signal having a greater dynamic range than the input signal. The expander circuit may be structured with a rectifying multiplier module to receive an alternating current (AC) portion of the input audio signal and generate a direct current (DC) voltage that is applied to a gain control input of a dynamic amplifier module. The dynamic amplifier module also including an input to receive the input audio signal and an output providing the expanded output audio signal.

### TECHNICAL FIELD

The present invention relates most generally to electronic signal waveshaping circuits. More particularly, the invention provides an improved and simply structured audio signal dynamic range expanding circuit.

### BACKGROUND ART

The intent of audio signal processing is most often to convert audio information, for example notes produced by an instrument, from a first form to a second form. Such a transformation may realized with the intent to minimize the distorting of the audio information—yielding a later reproduction or recreation that attempts to match the original. Alternately, other forms of audio signal processing are possible that purposefully create a desired distortion which may be said to ‘color’ the audio information. A classic example may be provided by reverberation units, which are well known in the art, and cause a delay between audio information that is delivered to different speakers of the same audio system. Such a coloring may be desirable, especially with particular forms of audio source content.

When considering the recording of live musical content, such as at an organized concert or recital, it is difficult to preserve the original dynamics and depth of the source version. That is, during playback the sound quality of recorded audio information can suffer significantly when compared to the original version. Some of the loss comes from physical limitations in the recording, reproduction, or playback hardware and algorithms employed thereby. Importantly, due to the large dynamic range of live musical events, live recordings are often compressed, reducing the dynamic range for recording purposes. As such, during playback recorded audio content may be expanded in an attempt to restore the original dynamic range of the audio information.

It may be noted that dynamic range expansion techniques may be employed with a variety of audio information. For example, in addition to the well known use of expanders with music, other applications may include:

i) vibration signal processing wherein the dynamic expansion of the audio content can aid in analysis to determine which frequencies, or ranges are frequencies, are predominate in the spectral content of the signal;

ii) sonar signal analysis, such as with passive sonar systems of submarines, to aid in analysis of received reflections from surface ships, other submarines, fish, etc.; and

iii) recorded airborne sounds to also aid in spectral analysis, for example related to stress or structural fatigue. The prior art includes an number of somewhat complicated audio signal processing systems that include dynamic range expansion. A first example of a somewhat complicated signal processing circuit that includes a variable gain amplifying element is seen in a utility patent to Ishimitsu (U.S. Pat. No. 5,255,325). The Ishimitsu device employees an input level detection section that can determine an instantaneous input signal level, for example peak input levels. A corresponding detection signal is fed to an amplifier and produces an output signal with a delay applied that varies with the level of the input signal. Accordingly, as the level of the input signal varies, a phase shift or delay is varied and applied to the output signal in an attempt to produce “audio signals which have less distortion than conventionally reproduced audio signals and which would sound more natural”. However, the ‘time constant setting section’ of this invention is a complicated structure, which is currently best implemented with a suitably programmed and structured digital signal processor (DSP) or an application specific integrated circuit (ASIC)—both of which may significantly complicate the design of an expander module. Also, it is believed that an additional complexity would be required to suitably accommodate varying types of audio content, such as classical music, rock music, spoken content, etc. Yet other examples of complicated expander circuits are found in the utility patents to Akagiri et al. (U.S. Pat. No. 4,972,164) and Fricke et al. (U.S. Pat. No. 4,381,488). Each of these inventions discloses devices that are quite complicated in structure, and while useful for there intended purposes, do not exhibit the features and advantages of the present invention. The Fricke invention provides for an adaptive system that varies the amount of dynamic range expansion provided as the level of ambient or background noise varies. This system includes a microphone as an important active element. As the ambient noise level increases, as sensed by the included microphone, the amount of audio signal expansion is increased. As the ambient noise level drops, the expansion is decreased.

The Akagiri device provides for an architecture employing a control signal generator in a fashion wherein multiplication, addition, and subtraction are each employed, via suitable hardware and or software means, to generate a desired processed and expanded signal. As stated above, the Akagiri invention is best implemented with DSP or ASIC devices, and as can be seen in the figures thereof, represents a complicated system best implemented via digital circuitry.

Therefore, skilled individuals will understand a need for simplified, improved, and efficient audio processing circuits that enable an audio signal applied thereto to be expanded to restore or enhance an original dynamic range of the applied audio signal. In particular, there is a need for improved audio expander circuits that are particularly suited for the expanding and restoring of audio input signals, such as produced at a concert or a recital. A full understanding of the present invention, including an understanding of a number of capabilities, characteristics, and associated novel features, will result from a careful review of the description and figures of several embodiments provided herein. Attention is called to the fact, however, that the drawings and descriptions are illustrative only. Variations and alternate embodiments are contemplated as being part of the invention, limited only by the scope of the appended claims.

### SUMMARY OF THE INVENTION

In accordance with the present invention, a dynamic range expander circuit is structured with an input to receive and process an input audio signal to provide an expanded output audio signal having a greater dynamic range than the input signal. The expanded output signal is provided at an output of the expander circuit. The dynamic range expander circuit includes a dynamic (gain) amplifier module and a rectifying multiplier module. The dynamic amplifier module is structured having at least one gain control input to receive a gain controlling direct current (DC) voltage to effect gain changes as a function of the instantaneous level of the DC voltage. The DC gain controlling voltage is generated in real time by the rectifying multiplier module, which includes an input to receive an alternating current (AC) portion of the input audio signal, and an output where the generated direct current (DC) voltage is available. The direct current (DC) voltage is most preferably directly proportional to an instantaneous average or peak value of the input audio signal.

One or more gain control inputs to the dynamic amplifier module are to be provided to enable the dynamic range of the input audio signal to be adjusted and expanded, as required. As such, as an applied gain controlling signal level increases, for example as a DC level thereof increases, the gain of the amplifier is increased. Similarly, as the DC level decreases, the gain is decreased. As will be understood by skilled individuals, the above described gain adjustments, provided as a function of the change in the level of one or more gain controlling signals, causes the dynamic range of the input audio signal to be increased or expanded. It should be noted that the dynamic range expansion discussed above may be selectively applied to a certain range of frequencies by including within the rectifying multiplier module filtering circuits that will enable one or more bands of frequencies to be coupled to, and rectified and multiplied by the module.

The dynamic range expander circuit may preferably include means to enable a user to adjust at least one of the following:

a) a level of the input audio signal coupled to the dynamic amplifier module;

b) a gain level of the rectifying multiplier module; and

c) a percentage of a direct current (DC) control signal coupled to a gain control input of the dynamic amplifier module; and

d) an output level of the expanded output audio signal generated by the dynamic amplifier module.

Preferably the above adjustments would be available via controls readily accessible by a user or operator. For example, such controls of the dynamic range expander circuit may be made available via a front panel user interface.

A most preferred embodiment of the present invention provides for a dynamic gain amplifier module, which may also be termed a dynamic amplifier module, based upon an electron tube having at least one control grid and at least one screen grid. The control grid is structured to receive an alternating current (AC) portion of the input audio signal and generate in real-time an inverted second direct current (DC) voltage, having a voltage potential that is below a common signal reference level. This second DC voltage will most preferably be inversely proportional to an instantaneous average or peak value of the input audio signal. A screen grid of the electron tube is coupled to the rectifying multiplier module to receive the first direct current (DC) voltage signal, causing the gain of the dynamic amplifier to be altered as discussed above.

A preferred method of the present invention provides for the efficient processing of an input audio signal to produce an output audio signal having an increased dynamic range. The method may commence with the sensing the input audio signal to determine the instantaneous or an averaged peak value. The sensed voltage level is processed by rectifying, multiplying, and generating a direct current (DC) voltage having a level that is substantially greater than the instantaneous peak value (of the sensed voltage). The generated direct current voltage is coupled, in real time, to a gain control input of an amplifier. The gain control input is thereby configured to receive the DC gain control signal to increase a gain level of the amplifier as the direct current voltage increases and decrease the gain level as the direct current voltage decreases. Accordingly, an expanding the dynamic range of the applied input audio signal is realized as the signal passes through the amplifier.

### BRIEF DESCRIPTION OF THE DRAWINGS

In the drawings, like elements are assigned like reference numerals. It must be understood that each of the embodiments depicted are but one of a number of possible structures and or arrangements utilizing the fundamental concepts of the present invention. The drawings are briefly described as follows:

FIG. 1 provides a high level block diagram of an audio signal expander apparatus in accordance with the invention;

FIG. 2 is a simplified high level block diagram of an embodiment of the invention employing a low noise pentode amplifying element.

FIG. 3 is a schematic diagram of a voltage quadrupler circuit.

FIG. 4 provides a detailed schematic diagram of a preferred embodiment a dynamic range expanding circuit of the invention.

### PARTIAL LIST OF REFERENCE NUMERALS

10—dynamic range expander circuit

12—dynamic (gain) amplifier module

14—coupler

16—gain-bias module

18—rectifying multiplier module (AC to DC)

18a—voltage quadrupler (AC to DC)

22—DC Bias Source

28—summing module

30—electron tube device

30a—control grid of 30

30b—screen grid of 30

50—input audio signal

50a—AC portion of input audio signal

54—first direct current (DC) voltage

58—second direct current (DC) voltage

60—expanded output audio signal

D₁-D₆—diodes

C₁-C₆—capacitors

VR₁—potentiometer, volume control

VR₂—potentiometer, bias control

VR₃—potentiometer, output level control

VR₄—potentiometer, expansion control

### DETAILED DESCRIPTION AND MODES OF THE INVENTION

It is important to establish a definition for several terms and expressions that will be used throughout this disclosure. The term ‘audio signal’ may be assumed to be any signal that is substantially within an audible frequency range. However, other signals, such as those at integral frequency multiplies of ‘inband’ signal, may be processed and passed by components of the present invention, as desired or needed. The terms ‘average direct current (DC) value’ and ‘direct current (DC) value’ may be assumed to indicate a DC level of a voltage or current, that is most preferably time varying in nature. As such, the DC level may follow or track an applied input audio signal. As such, The DC level will be assumed to increase with an increase in the level of the applied input audio signal, and will decrease with a decrease in the level of the input audio signal. In addition, the terms ‘level’ and ‘voltage’, ‘current’, and ‘value’, may be assumed to be equivalent, as determined by the context in which they are used. It may be further assumed that an instantaneous peak value may be considered generally equivalent to a time varying root mean square (RMS) level of an applied input audio signal, or an actual peak value of the input audio signal. Finally, the terms ‘coupled’, ‘coupled to’, and similar terms, are to be understood to mean that two components or items are either directly connected to one another, or alternately these items are coupled to each other via one or more additional interposed (possibly implied) structures and or components. Other important terms and definitions will be provided as they are needed, to properly and concisely define the present invention and its associated novel characteristics and features.

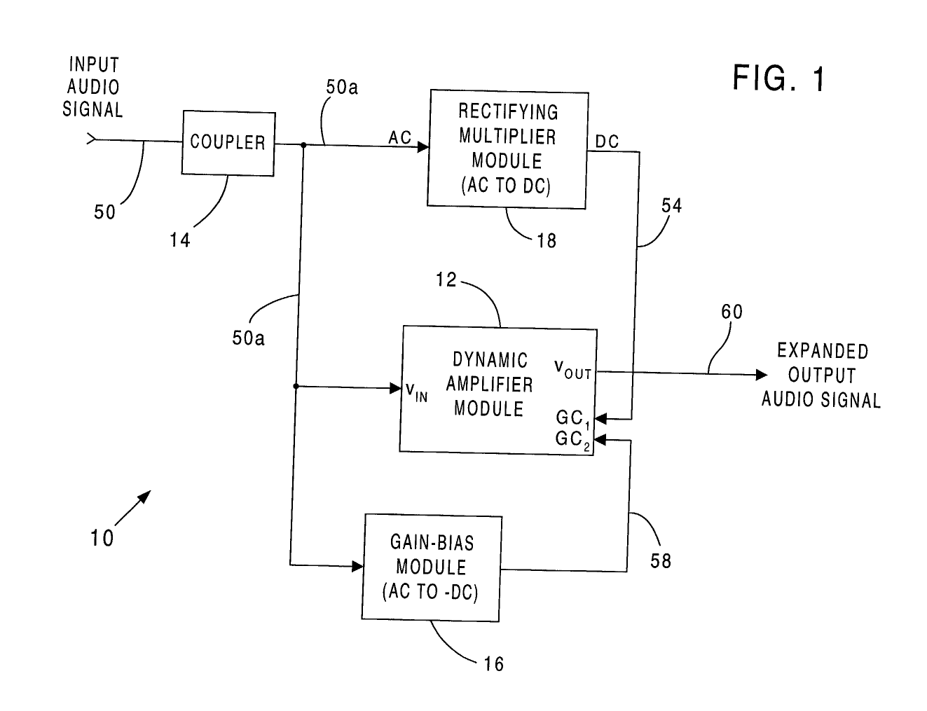

Referring now to the drawings, FIG. 1 depicts a dynamic range expander circuit 10 structured to receive and process an input audio signal 50, and provide an expanded output audio signal 60. Importantly, the expanded output audio signal has a greater dynamic range than the input signal. Preferred embodiments of the dynamic range expander circuit 10 include a rectifying multiplier module 18 that is configured to receive a portion 50a of the input audio signal 50. The received portion 50a, which may most preferably be an AC portion of the input audio signal 50, is then processed in real-time to generate a first direct current (DC) voltage 54 that is substantially proportional to a sensed instantaneous value of the input audio signal 50. The dynamic range expander circuit 10 further includes a dynamic amplifier module 12 having at least one gain control input. Each gain control input is configured to receive a direct current (DC) voltage. For example, as illustrated in FIG. 1, a first DC voltage 54 that is produced by the rectifying multiplier module 18 is coupled to gain control input GC1 of dynamic amplifier module 12. It may be noted that dynamic amplifier module 12 may be termed a ‘dynamic gain amplifier module’.

As can be further seen in FIG. 1, the dynamic amplifier module 12 is further structured with an input Vin to receive the input audio signal 50 and an output Vout providing the expanded output audio signal 60. As depicted, the input audio signal 50 may be coupled to the amplifier module 12 by way of a coupler 14, which may be provided to block any direct current (DC) portion of the input audio signal 50 applied to the dynamic range expander circuit 10.

The dynamic amplifier module 12 is structured to increase the gain of the amplifier, and the level of the expanded output audio signal 60 in several differing manners. First, and possibly most preferably, a full bandwidth input audio signal 50, for example with a minimum frequency range of 20 to 20K Hz, may be coupled to and received by the rectifying multiplier module 18. Alternately, the circuit 10 may be arranged to receive and couple to the rectifying multiplier module 18 at least one preselected range of frequencies. Each preselected range of frequencies thereby representing a portion of the full bandwidth input audio signal 50. Such bands of frequencies may be selected by suitable bandpass filter means of the rectifying and multiplying module 18 to receive only desired spectral portions of the input audio signal 50 or 50a. Accordingly, the spectral portion(s) of the input audio signal 50 may be selected and coupled to the rectifying multiplier module 18 causing the generating of an alternate or modified first direct current (DC) voltage 54 that will color an expanded output audio signal 60, as desired. Such ‘coloring’ of the expanded output audio signal may produce a desired effect or distortion. For example, it is contemplated that embodiments of the present invention will produce an effect wherein the dynamic range may be expanded to reproduce or approach a live audio event (such as a concert, etc.). Further, the dynamic amplifier module 12 is specifically structured to increase the gain of the amplifier module for the least one preselected range of frequencies as the direct current (DC) voltage increases. Similarly, the gain of the amplifier module 12 will decrease as a level of the direct current (DC) voltage decreases.

Returning to FIG. 1, there is also provided a gain-bias module 16. The gain-bias module 16 is structured to receive a portion 50a of the input audio signal 50 coupled thereto and produce a suitable direct current biasing signal 58. In preferred embodiments of the present invention the gain-bias module 16 is structured to receive an alternating current (AC) portion 50a of the input audio signal 50 and generate in real-time an inverted or negative potential ‘second’ direct current (DC) voltage 58. This inverted second DC voltage 58 having a voltage potential that is below a common signal ground reference level. Accordingly, this second DC voltage 58 may be said to be inversely proportional to an average value of the input audio signal 50. It may be noted that gain-bias module 16 may be configured to time average the input audio signal 50 thereby responding to an average loudness, and as such, may not track the instantaneous voltage as the rectifying multiplier module 18 most preferably does.

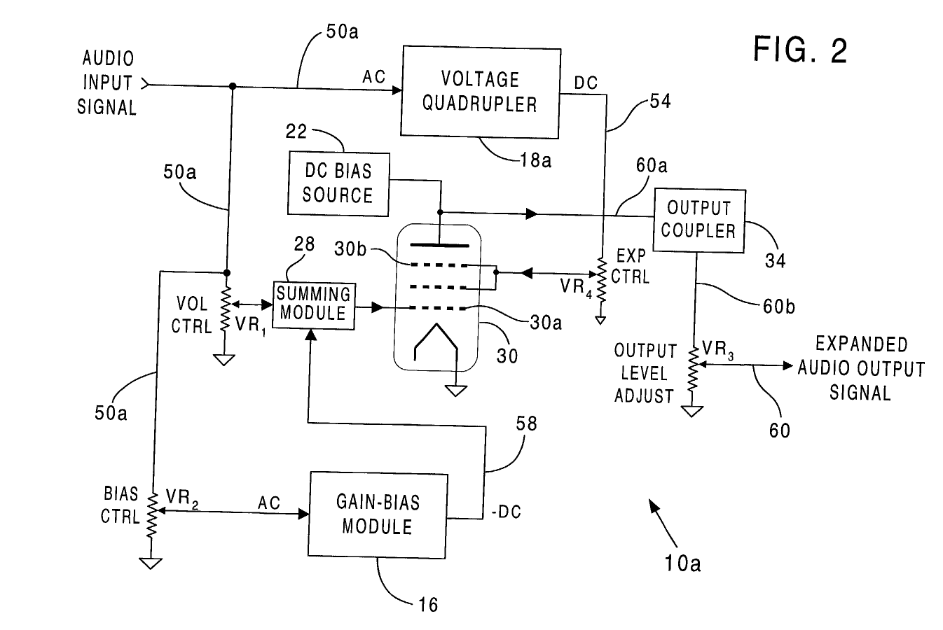

Turning now to FIG. 2, another preferred embodiment of the invention includes an electron tube 30 structured with a control grid 30a and at least one screen grid 30b. The electron tube 30 is provided with a DC bias source 22, which preferably provides a plate voltage for electron tube 30 that is in the range of 30 to 50 volts DC. As can be further seen in FIG. 2, this embodiment of the dynamic range expander circuit 10a may further include a summing module 28 which couples a portion 50a of the input audio signal 50, by way of a wiper or slide of a potentiometer VR1, and the second DC voltage 58 to the control grid 30a. As such, the control grid 30a is suitably biased, and also in an audio input to the electron tube 30 amplifier. As shown, this alternate embodiment has the control grid 30a coupled to the gain-bias module 16 to receive therefrom the second direct current (DC) voltage 58 signal. While at least one screen grid 30b is coupled to the rectifying multiplier module 18 to receive therefrom the first direct current (DC) voltage signal 54. Skilled individuals will understand that each of the first and second DC voltages, 54 and 58 respectively, may be termed ‘a gain controlling signal’.

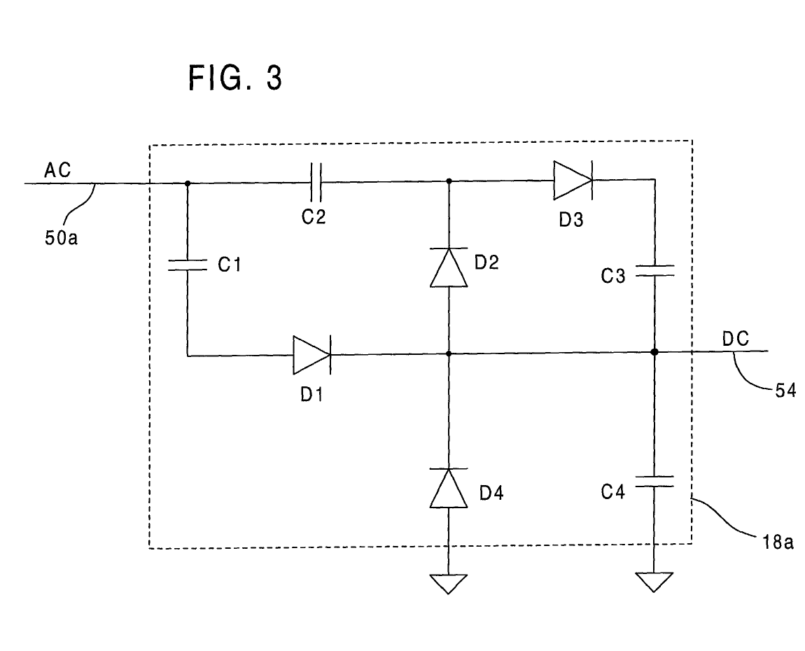

Returning to FIG. 2, a preferred embodiment of the rectifying multiplier module 18 is provided by voltage quadrupler 18a, which converts the input voltage 50a to a DC voltage 54 that is at least four times greater than a level of voltage 50a. Accordingly, the term quadrupler is often employed. A schematic of one possible embodiment of the voltage quadrupler 18 is provided in FIG. 3. As can be seen therein, an arrangement of capacitor elements (C1 through C4) and diode elements (D1 through D4) may provide a suitable voltage quadrupler means. Other equivalent circuits and modules may certainly be provided.

As indicated in FIG. 2, a portion of the actual DC voltage 54 applied to screen grid 30b may be selected by adjusting a slide element of potentiometer VR4. As can also be seen, the output signal 60a is passed through an output coupler 34 to remove a DC component thereof. The resulting signal 60b is coupled to potentiometer VR3, which provides a mechanism to selectively adjust the output level of the expanded output audio signal 60.

As indicated in FIGS. 2 and 3, and discussed above, a number of adjustments may be provided, for example as exemplified by the inclusion of potentiometers VR1 through VR4. Further, for convenience, the adjustments may be incorporated into a user interface. The user interface thereby enabling a user or operator of the dynamic range expander circuit 10 or 10a to adjust one or more ‘parameters’ associated with the input and or output audio signals. For example, a user interface may include at least one of the following means to: i) adjust the level of the input audio signal 50 coupled to the dynamic amplifier module 12; ii) adjust a ‘gain’ level of the rectifying multiplier module 18; iii) adjust a percentage of the first direct current (DC) signal couple to the gain control input of the dynamic amplifier module 12; and iv) adjust the output level of the expanded output audio signal 60 generated by the dynamic amplifier module 12. Other adjustments may be included with the various embodiments of the present invention, which may be provided by skilled individuals as a function of the actual respective implementations employed for differing embodiments.

Although preferred embodiments of the invention have been to this point exemplified by analog circuitry and concepts, skilled individuals will appreciate that other alternate embodiments are possible. For example, alternative architectures of the invention may implement methods of the invention using high speed digital signal processing circuitry. Such circuitry may be principally provided by off the shelf digital signal processors or application specific integrated circuits (ASICs), and well known support and ancillary circuitry.

An exemplary embodiment of such a method, providing for a processing of an input audio signal 50 to produce an expanded output audio signal 60 having an increased dynamic range may include the following steps. The method may commence with an activity wherein a sensing the input audio signal 50 is made, possibly at a pre-determined preferred sampling rate, to determine the instantaneous peak value of the audio signal. The sensed input audio signal 50 may then be processed, for example, by taking the absolute value and multiplying respective samples to provide a value that may be employed to control a programmed “dynamic amplification”. This step of taking the absolute value and multiplying, may be considered equivalent to generating a direct current (DC) voltage having a level that is substantially greater than the instantaneous peak value (of the input signal).

As indicated above, either an analog circuit or digital circuit approach enables a ‘dynamic gain amplifier device’ to be controlled in accordance with the invention. For example, the multiplied absolute values may be used as a multiplier in a software-based gain adjusting operation, just as a DC voltage was used to alter the dynamic amplifier module's gain in an analog embodiment. As such, the gain may be altered, as required, wherein the gain increases with increases in the input audio signal 50, and the gain decreases with decreases in the level of the input audio signal 50—producing the desired expanded output audio signal 60.

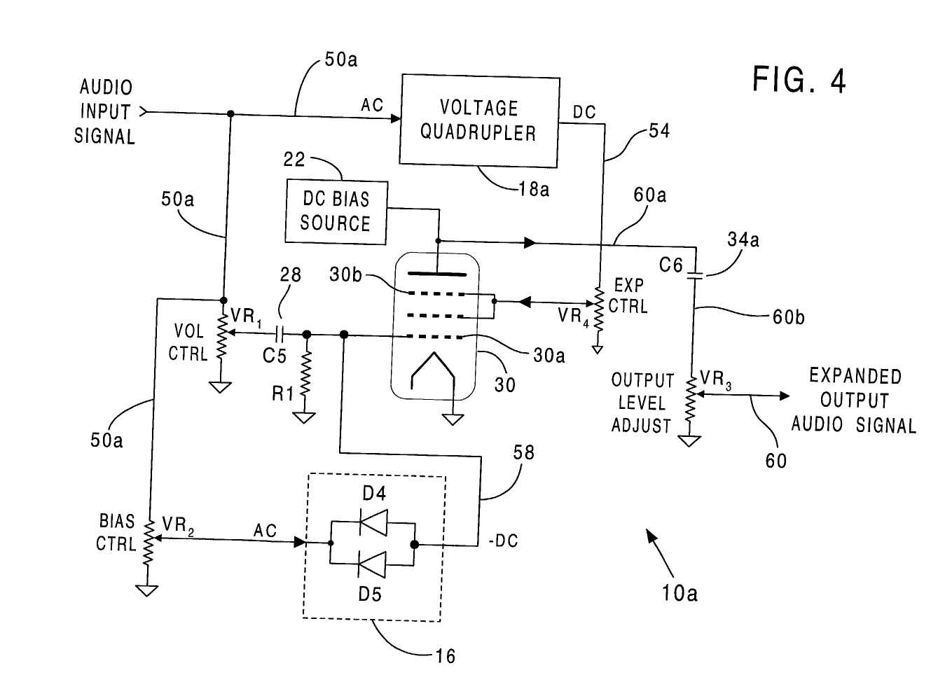

Turning to FIG. 4, there is provided a schematic diagram of a preferred embodiment a dynamic range expanding circuit of the invention. This embodiment includes a pair of diodes D5 and D6, which are arranged in a parallel configuration. It is the combination of diodes D4 and D5, along with resistor R1 that completes a portion of the gain-bias module 16. Additional components may be added to alter a time constant and other frequency related parameters and characteristics. These components are certainly providable by persons skilled in the art upon a review of this disclosure. It may also be noted that in the preferred embodiment of FIG. 4, a very simple and low-cost bias generating mechanism is provided by connecting the anodes of D4 and D5 directly to the control grid 30a. Other arrangements of circuit components, which may be preferred based on considerations other than cost, are certainly possible. For example, a summing module 28 may be provided as shown in FIG. 2.

While there have been described a plurality of the currently preferred embodiments of the present invention, those skilled in the art will recognize that other and further modifications may be made without departing from the invention and it is intended to claim all modifications and variations as fall within the scope of the invention and the appended claims.

What is claimed is:

1. A dynamic range expander circuit structured to receive and process an input audio signal to provide an expanded output signal having a greater dynamic range than the input audio signal, the dynamic range expander circuit comprising:
a) a rectifying multiplier module configured to receive an alternating current (AC) portion of the input audio signal and generate in real-time a first direct current (DC) voltage that is proportional to an instantaneous value of the input audio signal; and
b) a dynamic amplifier module having at least one gain control input to receive the first direct current (DC) voltage from the rectifying multiplier module, the dynamic amplifier module also including an input to receive the input audio signal and an output providing an expanded output audio signal;
c) the dynamic amplifier module structured to increase a gain of the amplifier module for at least one preselected range of frequencies as the first direct current (DC) voltage increases, and to decrease the gain of the amplifier module for at least one pre-selected range of frequencies as the first direct current (DC) voltage decreases.

2. The dynamic range expander circuit in accordance with claim 1, further including a user interface enabling a user or operator of the dynamic range expander circuit to adjust at least one of:
i) adjust a level of the input audio signal coupled to the dynamic amplifier module;
ii) adjust a gain level of the rectifying multiplier module;
iii) adjust a percentage of the first direct current (DC) signal coupled to a gain control input of the dynamic amplifier module; and
iv) adjust an output level of the expanded output audio signal generated by the dynamic amplifier module.

3. The dynamic range expander circuit in accordance with claim 2, further including a gain-bias module structured to receive an alternating current (AC) portion of the input audio signal and generate in real-time an inverted second direct current (DC) voltage, having a voltage potential that is below a common signal ground reference voltage, which is inversely proportional to an instantaneous peak value of the input audio signal.

4. The dynamic range expander circuit in accordance with claim 3, wherein the dynamic amplifier module includes an electron tube having:
a) a control grid that is coupled the gain-bias module to receive therefrom the second direct current (DC) voltage signal; and
b) a screen grid that is coupled to the rectifying multiplier module to receive therefrom the first direct current (DC) voltage signal.

5. The dynamic range expander circuit in accordance with claim 1, wherein the rectifying multiplier module generates in real-time a DC output level that is at least quadruple an associated input AC level.

6. The dynamic range expander circuit in accordance with claim 5, further including an input coupler configured to pass only an alternating current (AC) portion of an audio input signal applied to an input terminal of the dynamic range expander circuit.

7. A dynamic range expander circuit, comprising:
a) a rectifying multiplier module configured to receive an alternating current (AC) portion of an input audio signal, coupled to the expander circuit, and generate a first direct current (DC) voltage that is proportional to an instantaneous value of the input audio signal;
b) a dynamic amplifier module having at least one gain control input to receive the first direct current (DC) voltage from the rectifying multiplier module, the dynamic amplifier module also including an input to receive the input audio signal and an output providing the expanded output audio signal, wherein the dynamic amplifier module is structured to increase a gain of the amplifier module as the first direct current (DC) voltage increases, and to decrease a gain of the amplifier module as the first direct current (DC) voltage decreases.

8. The dynamic range expander circuit in accordance with claim 2, wherein the dynamic amplifier module includes an electron tube having a screen grid that is coupled to an output of the rectifying multiplier module to receive therefrom the first direct current (DC) voltage signal.

9. The dynamic range expander circuit in accordance with claim 8, wherein a level of the first direct current (DC) voltage signal coupled to a gain control input of the dynamic amplifier can be adjusted by a user to determine an amount of dynamic range expansion to be provided by the dynamic range expander circuit.

10. A method of processing an input audio signal to produce an output audio signal having an increased dynamic range, the method comprising the steps of:
a) sensing the input audio signal to determine an instantaneous peak value;
b) rectifying and multiplying an sensed input audio signal;
c) generating a direct current (DC) voltage having a level that is substantially greater than an instantaneous peak value; and
d) applying the direct current voltage to a gain control input of an amplifier, the gain control input configured to increase a gain level of the amplifier as the direct current voltage increases and decrease the gain level as the direct current voltage decreases, thereby expanding the dynamic range of the applied input audio signal.

11. The method according to claim 10, wherein the amplifier is provided by an electron tube amplifier having a control grid to which the input audio signal is coupled and a screen grid to which the direct current (DC) signal is coupled.
